(19) United States
(12) Patent Application Publication
(10) Pub. No.: US 2016/0217846 A1
(43) Pub. Date: Jul. 28, 2016

(54) SEMICONDUCTOR DEVICES CONFIGURED TO GENERATE A BANK ACTIVE SIGNAL

(71) Applicant: SK hynix Inc., Icheon-si (KR)

(72) Inventors: Chul Moon JUNG, Icheon-si (KR); Man Keun KANG, Seongnam-si (KR); Mi Hyun HWANG, Icheon-si (KR)

(21) Appl. No.: 14/705,157

(22) Filed: May 6, 2015

(30) Foreign Application Priority Data
Jan. 27, 2015 (KR) 10-2015-0012945

(51) Int. Cl. G11C 11/406; G11C 11/4076

(52) U.S. Cl. CPC G11C 11/40607; G11C 11/4076

(57) ABSTRACT

A semiconductor device may include a refresh controller and a bank active signal generator. The refresh controller may be suitable for generating a level signal, setting a level of the level signal in response to a refresh pulse signal while operating in a test mode, and suitable for receiving a refresh flag signal and generating a first period signal and a second period signal in response to the level signal. The bank active signal generator may be suitable for generating bank active signals for a first bank group in response to the first period signal, and generating bank active signals for a second bank group in response to the second period signal.

### CROSS-REFERENCE TO RELATED APPLICATIONS

The present application claims priority under 35 U.S.C 119(a) to Korean Application No. 10-2015-0012945, filed on Jan. 27, 2015, in the Korean Intellectual Property Office, which is incorporated herein by reference in its entirety as set forth in full.

### BACKGROUND

1. Technical Field

Various embodiments generally relate to semiconductor devices, and more particularly, to semiconductor devices configured to generate a bank active signal for executing a refresh operation.

2. Related Art

Semiconductor devices are typically categorized as either volatile memory devices or nonvolatile memory devices. Stored data within volatile memory devices is lost when power supplies to the volatile memory devices are interrupted. In contrast, stored data within nonvolatile memory devices is retained even when power supplies to the nonvolatile memory devices are interrupted. The volatile memory devices may include dynamic random access memory (DRAM) devices and static random access memory (SRAM) devices.

Each of the DRAM devices may include a cell array portion for storing digital information including a plurality of bits. The cell array portion of each DRAM device may include a plurality of cells, and each of the cells may include a single cell transistor and a single cell capacitor. Data of the digital information may be stored in the cell capacitors. Stored data within the DRAM devices is lost as time elapses even though power voltages to the DRAM devices are maintained. This may be due to leakage currents of the cell capacitors. Thus, to retain the stored data of the DRAM devices, the cell capacitors of the DRAM devices have to be periodically recharged or refreshed. This operation may be referred to as a refresh operation.

The DRAM devices are highly integrated and as the DRAM devices become more integrated, the cell array portion of each DRAM device may be divided into a plurality of banks. Each of the banks may be activated by a bank active signal to execute a refresh operation.

### SUMMARY

According to an embodiment, there may be provided a semiconductor device. The semiconductor device may include a refresh controller suitable for generating a level signal, setting a level of the level signal in response to a refresh pulse signal while operating in a test mode, and suitable for receiving a refresh flag signal and generating a first period signal and a second period signal in response to the level signal. The bank active signal generator may be suitable for generating bank active signals for a first bank group in response to the first period signal, and suitable for generating bank active signals for a second bank group in response to the second period signal.

According to an embodiment, there may be provided a semiconductor device. The semiconductor device may include a refresh pulse generator suitable for generating a refresh pulse signal in response to a mode signal. The semiconductor device may include a level signal generator suitable for generating a level signal in response to a refresh pulse signal. The semiconductor device may include a period signal generator suitable for generating a first period signal and a second period signal from a refresh flag signal in response to the level signal. The semiconductor device may include a bank active signal generator suitable for generating bank active signals for a first bank group in response to the first period signal, and suitable for generating bank active signals for a second bank group in response to the second period signal.

### BRIEF DESCRIPTION OF THE DRAWINGS

FIG. 1 is a block diagram illustrating a representation of an example of a semiconductor device according to an embodiment.

FIG. 2 is a circuit diagram illustrating a representation of an example of a flag signal generator.

FIG. 3 is a logic circuit diagram illustrating a representation of an example of a period signal generator included in the semiconductor device of FIG. 1.

FIG. 4 is a block diagram illustrating a representation of an example of a bank active signal generator included in the semiconductor device of FIG. 1.

FIG. 5 is a timing diagram illustrating a representation of an example of an operation of the semiconductor device illustrated in FIG. 1.

FIG. 6 is a block diagram illustrating a representation of an example of a semiconductor device according to an embodiment.

FIG. 7 illustrates a block diagram of an example of a representation of a system employing a semiconductor device in accordance with the various embodiments discussed above with relation to FIGS. 1-6.

### DETAILED DESCRIPTION

Various embodiments of the present disclosure will be described hereinafter with reference to the accompanying drawings. However, the embodiments described herein are for illustrative purposes only and are not intended to limit the scope of the present disclosure.

Various examples of the embodiments may be directed to semiconductor devices configured to generate a bank active signal for executing a refresh operation.

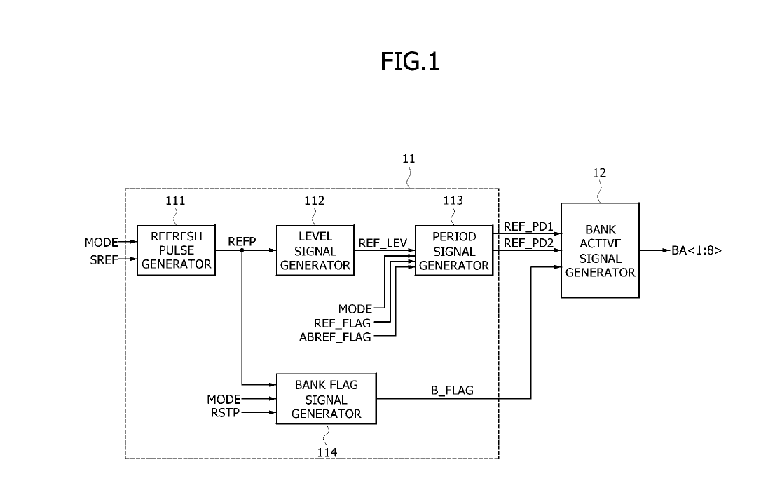

Referring to FIG. 1, a semiconductor device according to an embodiment may include a refresh controller 11 and a bank active signal generator 12. The refresh controller 11 may include a refresh pulse generator 111, a level signal generator 112, and a period signal generator 113. The refresh controller 11 may include a bank flag signal generator 114.

The refresh pulse generator 111 may be configured to generate a refresh pulse signal REFP. The refresh pulse signal REFP may be generated in response to a mode signal MODE and a self-refresh signal SREF. The mode signal MODE may be enabled while the refresh controller 11 is operating in a test mode. The self-refresh signal SREF may be enabled during a self-refresh operation. The refresh pulse generator 111 may generate the refresh pulse signal REFP including a plurality of pulses. The plurality of pulses of the refresh pulse signal REFP may periodically occur during the test mode or the self-refresh operation. A cycle time of the refresh pulse signal REFP may be set to be different according to the various embodiments.

The level signal generator 112 may generate a level signal REF_LEV. The level signal REF_LEV may be generated in response to a refresh pulse signal REFP. Level transitions of the level signal REF_LEV may occur whenever the pulses of the refresh pulse signal REFP are generated. Levels of the level signal REF_LEV may be set to be different according to the various embodiments.

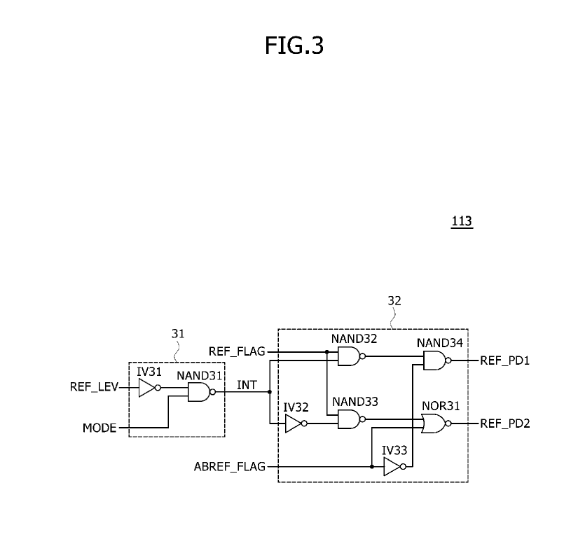

The period signal generator 113 may generate a first period signal REF_PD1 and a second period signal REF_PD2. The first period signal REF_PD1 and the second period signal REF_PD2 may be generated in response to the level signal REF_LEV, the mode signal MODE, a refresh flag signal REF_FLAG and an all bank refresh flag signal ABREF_FLAG. The refresh flag signal REF_FLAG may be enabled while a refresh operation to each of banks included in the semiconductor device is executed. The all bank refresh flag signal ABREF_FLAG may be enabled while an all bank refresh operation is executed. While the refresh controller 11 is operating test mode, the period signal generator 113 may buffer the refresh flag signal REF_FLAG to selectively output the first or second period signal REF_PD1 or REF_PD2 according to a level of the level signal REF_LEV while the enabled mode signal MODE is inputted thereto. The period signal generator 113 may generate the first period signal REF_PD1 enabled to have a logic “high” level and the second period signal REF_PD2 disabled to have a logic “low” level if the enabled all bank refresh flag signal ABREF_FLAG is inputted thereto while the all bank refresh operation is executed. A configuration and an operation of the period signal generator 113 will be described with reference to FIG. 3 later.

The bank flag signal generator 114 may receive the refresh pulse signal REFP, the mode signal MODE, and a reset pulse signal RSTP to generate a bank flag signal B_FLAG. The bank flag signal B_FLAG may be set to have a predetermined level during a period that each of bank groups included in the semiconductor device is refreshed while the semiconductor device is operating in the test mode. The number of the bank groups may be two or more. For example, if the semiconductor device has eight banks, the eight banks may be divided into a first bank group and a second bank group so that each of the first and second bank groups includes four banks. In such an example, the bank flag signal B_FLAG may be set to have a first predetermined level while the first bank group is refreshed while the semiconductor device is operating in the test mode and a second predetermined level while the second bank group is refreshed while the semiconductor device is operating in the test mode. In some embodiments, the first and second predetermined levels may be the same level.

The bank active signal generator 12 may execute a refresh operation of the banks included in the semiconductor device in response to the bank flag signal B_FLAG, the first period signal REF_PD1, and the second period signal REF_PD2. For example, the bank active signal generator 12 may generate first to fourth bank active signals BA<1:4> to execute a refresh operation of first to fourth banks included in the first bank group while the first period signal REF_PD1 is enabled. For example, the bank active signal generator 12 may generate fifth to eighth bank active signals BA<5:8> to execute a refresh operation of fifth to eighth banks included in the second bank group while the second period signal REF_PD2 is enabled.

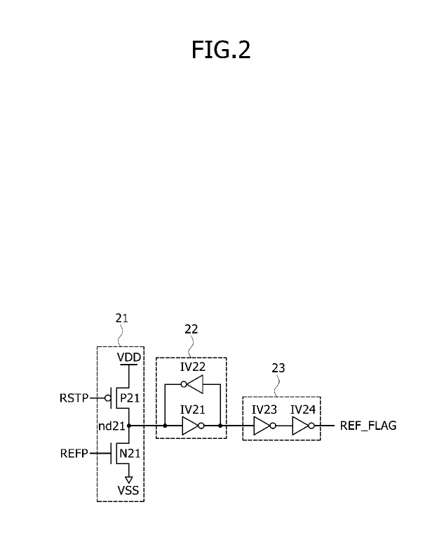

Referring to FIG. 2, an example of a flag signal generator for generating the refresh flag signal REF_FLAG is illustrated. The flag signal generator may include a pulse input unit 21 (i.e., pulse input unit 21 or pulse input device 21), a latch unit 22 (i.e., latch unit 22 or latch device 22) and a buffer unit 23 (i.e., buffer unit 23 or buffer device 23). The pulse input unit 21 may act as an internal node driver. The pulse input unit 21 may include a PMOS transistor P21 and an NMOS transistor N21. The PMOS transistor P21 and the NMOS transistor N21 may be coupled in series between a power supply voltage VDD terminal and a ground voltage VSS terminal. The PMOS transistor P21 may pull up an internal node ND21 to the power supply voltage VDD if a pulse of the reset pulse signal RSTP occurs. The NMOS transistor N21 may pull down the internal node ND21 to the ground voltage VSS if a pulse of the refresh pulse signal REFP occurs. The reset pulse signal RSTP may be generated to have a logic “low” level at a point of time when the refresh operation of the first bank group terminates and at a point of time when the refresh operation of the second bank group terminates. The latch unit 22 may include inverters IV21 and IV22. The latch unit 22 may latch may buffer and latch a signal of the internal node ND21 and may output the buffed and latched signal. The buffer unit 23 may include inverters IV23 and IV24. The inverters IV23 and IV24 may be cascaded. The buffer unit 23 may buffer an output signal of the latch unit 22 and may output the buffered signal as the refresh flag signal REF_FLAG. While the refresh operations of the first and second bank groups are executed, the refresh flag signal REF_FLAG generated from the flag signal generator may be enabled to have a logic “high” level.

Referring to FIG. 3, the period signal generator 113 may include an internal signal generation unit 31 (i.e., internal signal generation unit 31 or internal signal generation device) and a period signal output unit 32 (i.e., period signal output unit 32 or period signal output device 32). The internal signal generation unit 31 may include an inverter IV31 and a NAND gate NAND31. The internal signal generation unit 31 may buffer the level signal REF_LEV to generate an internal signal INT while the mode signal MODE having a logic “high” level is inputted thereto while operating in the test mode. The period signal output unit 32 may include inverters IV32 and IV33. The period signal output inti 32 may include NAND gates NAND32, NAND33 and NAND34, and a NOR gate NOR31. The period signal output unit 32 may buffer the refresh flag signal REF_FLAG to output the refresh flag signal REF_FLAG as the first period signal REF_PD1 if the internal signal INT has a logic “high” level while operating in the test mode. The period signal output unit 32 may buffer the refresh flag signal REF_FLAG to output the refresh flag signal REF_FLAG as the second period signal REF_PD2 if the internal signal INT has a logic “low” level while operating in the test mode. If the all bank refresh flag signal ABREF_FLAG enabled to have a logic “high” level is inputted to the period signal output unit 32 during the all bank refresh operation, the period signal output unit 32 may generate the first period signal REF_PD1 enabled to have a logic “high” level and the second period signal REF_PD2 disabled to have a logic “low” level.

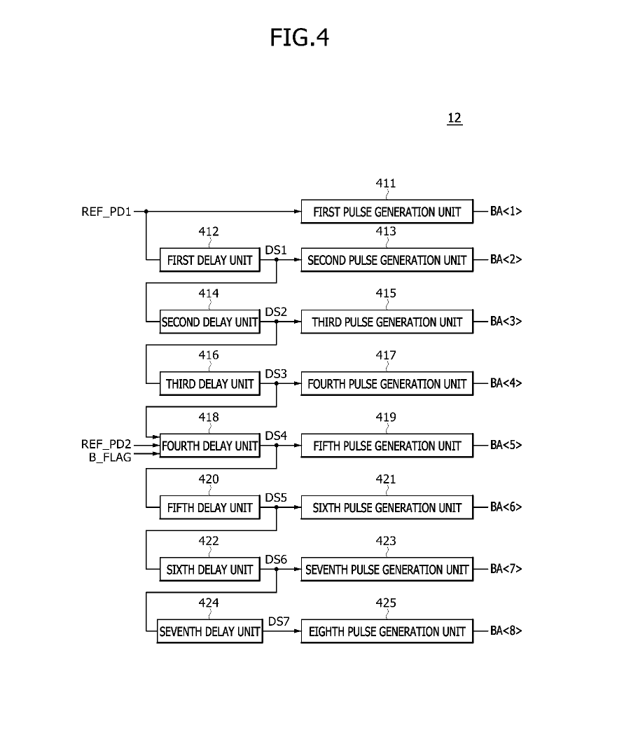

Referring to FIG. 4, the bank active signal generator 12 may include a first pulse generation unit 411 (i.e., unit or device), a first delay unit 412, and a second pulse generation unit 413. The bank active signal generator 12 may include a second delay unit 414, a third pulse generation unit 415, and a third delay unit 416. The bank active signal generator 12 may include a fourth pulse generation unit 417, a fourth delay unit 418, and a fifth pulse generation unit 419. The bank active signal generator 12 may include a fifth delay unit 420, a sixth pulse generation unit 421, and a sixth delay unit 422. The bank active signal generator 12 may include a seventh pulse generation unit 423, a seventh delay unit 424 and an eighth pulse generation unit 425.

The first pulse generation unit 411 may generate a pulse of the first bank active signal BA<1> for refreshing a first bank included in the first bank group in synchronization with a point of time when the first period signal REF_PD1 is enabled. The first delay unit 412 may retard the first period signal REF_PD1 by a predetermined period to generate a first delay signal DS1. The second pulse generation unit 413 may generate a pulse of the second bank active signal BA<2> for refreshing a second bank included in the first bank group in synchronization with a point of time when the first delay signal DS1 is enabled. The second delay unit 414 may retard the first delay signal DS1 by a predetermined period to generate a second delay signal DS2. The third pulse generation unit 415 may generate a pulse of the third bank active signal BA<3> for refreshing a third bank included in the first bank group in synchronization with a point of time when the second delay signal DS2 is enabled. The third delay unit 416 may retard the second delay signal DS2 by a predetermined period to generate a third delay signal DS3. The fourth pulse generation unit 417 may generate a pulse of the fourth bank active signal BA<4> for refreshing a fourth bank included in the first bank group in synchronization with a point of time when the third delay signal DS3 is enabled.

The fourth delay unit 418 may retard the second period signal REF_PD2 or the third delay signal DS3 by a predetermined period in response to the bank flag signal B_FLAG to generate a fourth delay signal DS4. The fourth delay unit 418 may retard the second period signal REF_PD2 by a predetermined period to generate the fourth delay signal DS4 while the bank flag signal B_FLAG having a logic “high” level is inputted thereto while operating in the test mode. The fourth delay unit 418 may retard the third delay signal DS3 by a predetermined period to generate the fourth delay signal DS4 if the bank flag signal B_FLAG having a logic “low” level is inputted thereto while the all bank refresh operation is executed. The fifth pulse generation unit 419 may generate a pulse of the fifth bank active signal BA<5> for refreshing a fifth bank included in the second bank group in synchronization with a point of time when the fourth delay signal DS4 is enabled. The fifth delay unit 420 may retard the fourth delay signal DS4 by a predetermined period to generate a fifth delay signal DS5. The sixth pulse generation unit 421 may generate a pulse of the sixth bank active signal BA<6> for refreshing a sixth bank included in the second bank group in synchronization with a point of time when the fifth delay signal DS5 is enabled. The sixth delay unit 422 may retard the fifth delay signal DS5 by a predetermined period to generate a sixth delay signal DS6. The seventh pulse generation unit 423 may generate a pulse of the seventh bank active signal BA<7> for refreshing a seventh bank included in the second bank group in synchronization with a point of time when the sixth delay signal DS6 is enabled. The seventh delay unit 424 may retard the sixth delay signal DS6 by a predetermined period to generate a seventh delay signal DS7. The eighth pulse generation unit 425 may generate a pulse of the eighth bank active signal BA<8> for refreshing an eighth bank included in the second bank group in synchronization with a point of time when the seventh delay signal DS7 is enabled.

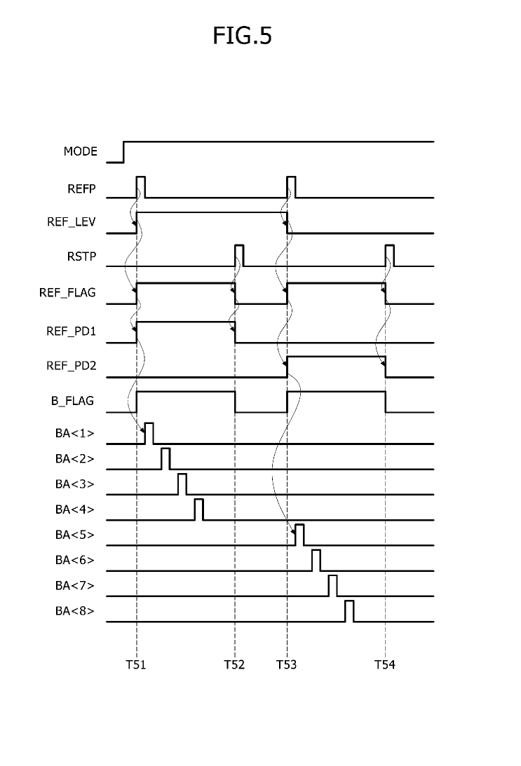

An operation of the semiconductor device having the aforementioned configuration will be described hereinafter with reference to FIG. 5.

First, if the mode signal MODE is enabled to have a logic “high” level while operating in the test mode for testing the semiconductor device, pulses of the refresh pulse signal REFP may occur at a point of time “T51” and a point of time “T53”, respectively.

Level transitions of the level signal REF_LEV may occur in response to the pulses of the refresh pulse signal REFP. For example, a level of the level signal REF_LEV may be changed from a logic “low” level to a logic “high” level if the first pulse of the refresh pulse signal REFP occurs at the point of time “T51”. A level of the level signal REF_LEV may be changed from a logic “high” level to a logic “low” level if the second pulse of the refresh pulse signal REFP occurs at the point of time “T53”.

The refresh flag signal REF_FLAG may be generated in response to the pulses of the refresh pulse signal REFP and the pulses of the reset pulse signal RSTP. The pulses of the reset pulse signal RSTP may occur at a point of time “T52” that a refresh operation of the first bank group including the first to fourth banks terminates and at a point of time “T54” that a refresh operation of the second bank group including the fifth to eighth banks terminates, respectively. The refresh flag signal REF_FLAG may be enabled to have a logic “high” level from the point of time “T51” till the point of time “T52” in order to execute a refresh operation of the first bank group and from the point of time “T53” till the point of time “T54” in order to execute a refresh operation of the second bank group.

While operating in the test mode, the first and second period signals REF_PD1 and REF_PD2 may be generated from the refresh flag signal REF_FLAG in response to the level signal REF_LEV. For example, a buffered signal of the refresh flag signal REF_FLAG may be outputted as the first period signal REF_PD1 during a period from the point of time “T51” until the point of time “T52” while the test mode signal MODE has a logic “high” level. For example, a buffered signal of the refresh flag signal REF_FLAG may be outputted as the second period signal REF_PD2 during a period from the point of time “T53” until the point of time “T54” while the test mode signal MODE has a logic “high” level.

Pulses of the first to fourth bank active signals BA<1:4> may sequentially occur to refresh the first bank group during a period from the point of time “T51” until the point of time “T52”. The pulses of the first to fourth bank active signals BA<1:4> may be generated from the delay signals (DS1, DS2 and DS3 of FIG. 4), the delay signals generated by sequentially retarding the first period signal REF_PD1. Pulses of the fifth to eighth bank active signals BA<5:8> may sequentially occur to refresh the second bank group during a period from the point of time “T53” till the point of time “T54”. The pulses of the fifth to eighth bank active signals BA<5:8> may be generated from the delay signals (DS4, DS5, DS6 and DS7 of FIG. 4), the delay signals generated by sequentially retarding the second period signal REF_PD2 during the period from the point of time “T53” until the point of time “T54” that the bank flag signal B_FLAG is set to have a logic “high” level.

A semiconductor device according to an embodiment may include a plurality of bank groups, each of bank groups may comprise a plurality of banks, and each bank group may be separately refreshed. A refresh period may be reduced as compared with a case whereby all of the banks are separately refreshed. As a result, the abrupt and abnormal termination of a refresh operation may be prevented to reduce the probability of malfunction of the semiconductor device.

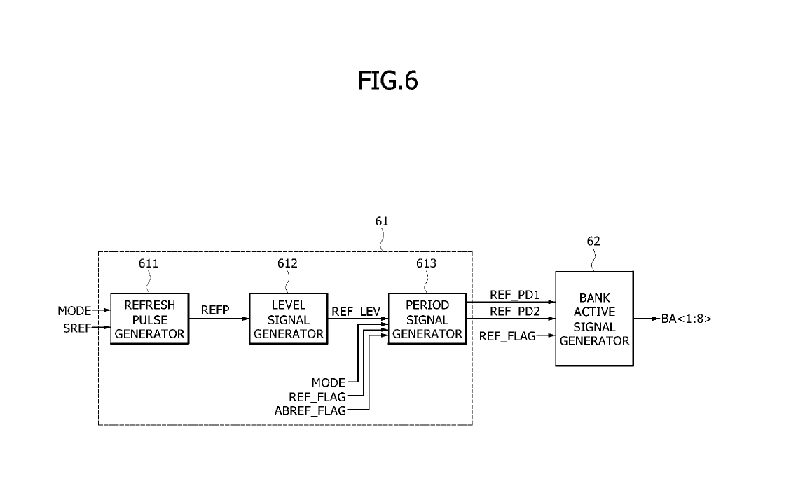

Referring to FIG. 6, a semiconductor device according to an embodiment may include a refresh controller 61 and a bank active signal generator 62. The refresh controller 11 may include a refresh pulse generator 611, a level signal generator 612 and a period signal generator 613. The semiconductor device illustrated in FIG. 6 may have substantially the same configuration and operation as the semiconductor device illustrated in FIGS. 1 to 5 except that the bank active signal generator 62 generates the bank active signals BA<1:8> using the refresh flag signal REF_FLAG instead of the bank flag signal B_FLAG. Thus, a detailed description of the semiconductor device illustrated in FIG. 6 will be omitted.

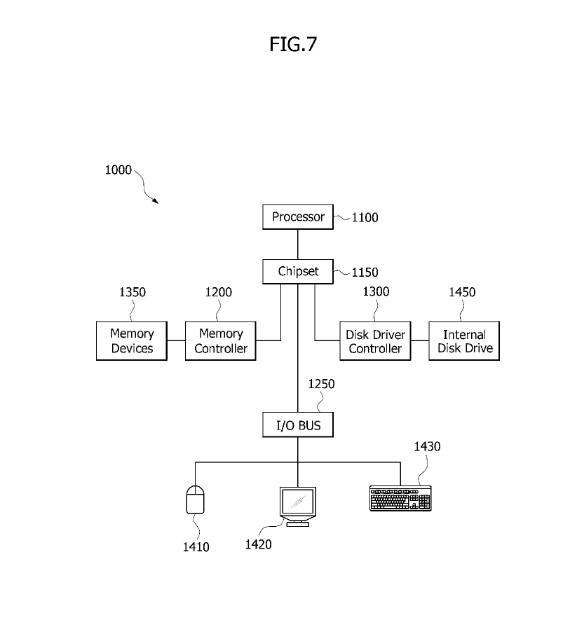

The semiconductor device discussed above (see FIGS. 1-6) are particular useful in the design of memory devices, processors, and computer systems. For example, referring to FIG. 7, a block diagram of a system employing the semiconductor device in accordance with the various embodiments are illustrated and generally designated by a reference numeral 1000. The system 1000 may include one or more processors or central processing units (“CPUs”) 1100. The CPU 1100 may be used individually or in combination with other CPUs. While the CPU 1100 will be referred to primarily in the singular, it will be understood by those skilled in the art that a system with any number of physical or logical CPUs may be implemented.

A chipset 1150 may be operably coupled to the CPU 1100. The chipset 1150 is a communication pathway for signals between the CPU 1100 and other components of the system 1000, which may include a memory controller 1200, an input/output (“I/O”) bus 1250, and a disk drive controller 1300. Depending on the configuration of the system, any one of a number of different signals may be transmitted through the chipset 1150, and those skilled in the art will appreciate that the routing of the signals throughout the system 1000 can be readily adjusted without changing the underlying nature of the system.

As stated above, the memory controller 1200 may be operably coupled to the chipset 1150. The memory controller 1200 may include at least one semiconductor device as discussed above with reference to FIGS. 1-6. Thus, the memory controller 1200 can receive a request provided from the CPU 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the at least one semiconductor device as discussed above with relation to FIGS. 1-6, the memory devices 1350 may include a plurality of word lines and a plurality of bit lines for defining a plurality of memory cells. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420, and 1430. Further, the I/O bus 1250 may be integrated into the chipset 1150.

The disk drive controller 1450 (i.e., internal disk drive) may also be operably coupled to the chipset 1150. The disk drive controller 1450 may serve as the communication pathway between the chipset 1150 and one or more internal disk drives 1450. The internal disk drive 1450 may facilitate disconnection of the external data storage devices by storing both instructions and data. The disk drive controller 1300 and the internal disk drives 1450 may communicate with each other or with the chipset 1150 using virtually any type of communication protocol, including all of those mentioned above with regard to the I/O bus 1250.

It is important to note that the system 1000 described above in relation to FIG. 7 is merely one example of a system employing the semiconductor device as discussed above with relation to FIGS. 1-6. In alternate embodiments, such as cellular phones or digital cameras, the components may differ from the embodiments illustrated in FIG. 7.

What is claimed is:

1. A semiconductor device comprising:
a refresh controller suitable for generating a level signal, setting a level of the level signal in response to a refresh pulse signal while operating in a test mode, and suitable for receiving a refresh flag signal and generating a first period signal and a second period signal in response to the level signal; and
a bank active signal generator suitable for generating bank active signals for a first bank group in response to the first period signal, and suitable for generating bank active signals for a second bank group in response to the second period signal.

2. The semiconductor device of claim 1, wherein the refresh pulse signal is generated to include a predetermined cycle time while operating in the test mode.

3. The semiconductor device of claim 1, wherein a level transition of the level signal occurs whenever pulses of the refresh pulse signal occur.

4. The semiconductor device of claim 1, wherein the refresh flag signal is enabled while the first bank group and the second bank group are refreshed in response to the refresh pulse signal and a reset pulse signal while operating in the test mode.

5. The semiconductor device of claim 1, further comprising a flag signal generator, the flag signal generator including:
a pulse input device suitable for receiving the refresh pulse signal and a reset pulse signal to drive an internal node;
a latch unit suitable for buffering and latching a signal of the internal node; and
a buffer unit suitable for receiving an output signal of the latch unit and for buffering the output signal of the latch unit to generate the refresh flag signal while operating in the test mode.

6. The semiconductor device of claim 5, wherein the refresh controller includes a period signal generator suitable for generating the first and second period signals from the refresh flag signal in response to the level signal while operating in the test mode.

7. The semiconductor device of claim 6, wherein the period signal generator includes:
an internal signal generation unit suitable for generating an internal signal from the level signal in response to a mode signal; and
a period signal output unit suitable for buffering the refresh flag signal to output the first period signal or the second period signal according to a level of the internal signal.

8. The semiconductor device of claim 1, wherein the first period signal is disabled and the second period signal is enabled if an all bank refresh operation is executed.

9. The semiconductor device of claim 6,
wherein the refresh controller further includes:
a bank flag signal generator suitable for receiving the refresh pulse signal, the mode signal, and the reset pulse signal to generate a bank flag signal, and
wherein the bank active signal generator includes:
a first pulse generation unit suitable for generating a pulse of a first bank active signal for refreshing a first bank included in the first bank group in response to the first period signal;
a first delay unit suitable for retarding the first period signal to generate a first delay signal; and
a second pulse generation unit suitable for generating a pulse of a second bank active signal for refreshing a second bank included in the first bank group in response to the first delay signal.

10. The semiconductor device of claim 9, wherein the bank active signal generator further includes:
a second delay unit suitable for retarding the first delay signal in response to the second period signal and the bank flag signal to generate a second delay signal; and
a third pulse generation unit suitable for generating a pulse of a third bank active signal for refreshing a third bank included in the second bank group in response to the second delay signal.

11. The semiconductor device of claim 9, wherein the bank active signal generator further includes:
a second delay unit suitable for retarding the first delay signal in response to the second period signal and the refresh flag signal to generate a second delay signal; and
a third pulse generation unit suitable for generating a pulse of a third bank active signal for refreshing a third bank included in the second bank group in response to the second delay signal.

12. The semiconductor device of claim 10, wherein the bank flag signal is set to have a predetermined level while the first and second bank groups are refreshed.

13. A semiconductor device comprising:
a refresh pulse generator suitable for generating a refresh pulse signal in response to a mode signal;
a level signal generator suitable for generating a level signal in response to a refresh pulse signal;
a period signal generator suitable for generating a first period signal and a second period signal from a refresh flag signal in response to the level signal; and
a bank active signal generator suitable for generating bank active signals for a first bank group in response to the first period signal, and suitable for generating bank active signals for a second bank group in response to the second period signal.

14. The semiconductor device of claim 13, wherein the refresh pulse generator generates the refresh pulse signal including a predetermined cycle time if the mode signal is enabled while operating in a test mode.

15. The semiconductor device of claim 13,
wherein the level signal generator generates the level signal, and
wherein a level of the level signal transitions whenever pulses of the refresh pulse signal occur.

16. The semiconductor device of claim 13, wherein the refresh flag signal is enabled while the first and second bank groups are refreshed in response to the refresh pulse signal and a reset pulse signal during a period when the mode signal is enabled.

17. The semiconductor device of claim 13, wherein the period signal generator includes:
an internal signal generation unit suitable for generating an internal signal from the level signal in response to the mode signal; and
a period signal output unit suitable for buffering the refresh flag to output the first period signal or the second period signal according to a level of the internal signal.

18. The semiconductor device of claim 13, wherein the first period signal is disabled and the second period signal is enabled if an all bank refresh operation is executed.

19. The semiconductor device of claim 16,
wherein the semiconductor device further includes:
a bank flag signal generator suitable for receiving the refresh pulse signal, the mode signal, and the reset pulse signal to generate a bank flag signal, and
wherein the bank active signal generator includes:
a first pulse generation unit suitable for generating a pulse of a first bank active signal for refreshing a first bank included in the first bank group in response to the first period signal;
a first delay unit suitable for retarding the first period signal to generate a first delay signal; and
a second pulse generation unit suitable for generating a pulse of a second bank active signal for refreshing a second bank included in the first bank group in response to the first delay signal.

20. The semiconductor device of claim 19, wherein the bank active signal generator further includes:
a second delay unit suitable for retarding the first delay signal in response to the second period signal and the bank flag signal to generate a second delay signal; and
a third pulse generation unit suitable for generating a pulse of a third bank active signal for refreshing a third bank included in the second bank group in response to the second delay signal.

21. The semiconductor device of claim 19, wherein the bank active signal generator further includes:
a second delay unit suitable for retarding the first delay signal in response to the second period signal and the refresh flag signal to generate a second delay signal; and
a third pulse generation unit suitable for generating a pulse of a third bank active signal for refreshing a third bank included in the second bank group in response to the second delay signal.

22. The semiconductor device of claim 20, wherein the bank flag signal is set to have a predetermined level while the first and second bank groups are refreshed.
